(19) United States
(12) Patent Application Publication
(10) Pub. No.: US 2002/0088628 A1
(43) Pub. Date: Jul. 11, 2002

(54) EMI protective I/O connector holder plate

(76) Inventor: Shih Hui Chen, Taoyuan Hsien (TW)

Correspondence Address: DOUGHERTY & TROXELL, Suite 1404, 5205 Leesburg Pike, Falls Church, VA, 22041, US

(21) Appl. No.: 09/756,657

(22) Filed: Jan. 10, 2001

(51) Int. Cl. H05K 9/00

(52) U.S. Cl. 174/35 R

(57) ABSTRACT

An EMI (electromagnetic interference) protective I/O connector holder plate formed of an electrically conductive shell and a foamed lining and back-glued and adhered to the back sidewall of a case for computer and having a plurality of insertion holes for the mounting of I/O connectors. The electrically conductive shell is composed of a layer of thermofusion gums, a layer of aluminum foil, a layer of cotton cloth 1, and a layer of polyester film.

### BACKGROUND OF THE INVENTION

The present invention relates to an I/O connector holder plate and, more particularly, to an EMI (electromagnetic interference) protective I/O connector holder plate adapted for fastening to the back sidewall of a case for computer to hold I/O connectors.

FIGS. 1 and 2 show a metal I/O connector holder plate for computer according to the prior art. The metal I/O connector holder plate 1′ comprises a plurality of insertion holes 12′ adapted to receive I/O connectors 4 individually, and protruded spring strips 11′ suspended in the insertion holes 12′ and adapted to hold down inserted I/O connectors 4 in the respective insertion holes 12′. Because the contact area between the metal I/O connector holder plate 1′ and each inserted I/O connector 4 is limited to few contact points, the positioning of each I/O connector 4 in each insertion hole 12′ is unstable. This design cannot well protect the installed I/O connectors 4 against EMI (electromagnetic interference). There is also known another structure of metal I/O connector holder plate, which comprises raised portions and spring strips spaced around each I/O connector insertion hole. This design still cannot well protect the installed I/O connectors against EMI.

### SUMMARY OF THE INVENTION

The present invention has been accomplished to provide an EMI protective I/O connector holder plate, which eliminates the aforesaid drawbacks. According to one aspect of the present invention, the EMI protective I/O connector holder plate is comprised of a foamed lining and an electrically conductive shell covered on the foamed lining. Because of the effect of the foamed lining, installed I/O connectors are peripherally sealed and positively secured in position. According to another aspect of the present invention, the foamed lining is formed of multiple layers of foamed materials of different hardness.

### BRIEF DESCRIPTION OF THE DRAWINGS

FIG. 1 is a perspective view of a metal I/O connector holder plate for computer according to the prior art.

FIG. 2 is a top view in section of the prior art metal I/O connector holder plate showing an I/O connector installed.

FIG. 3 is an elevational view of an EMI protective I/O connector holder plate according to the present invention.

FIG. 4 is a sectional view in an enlarged scale taken along line 4-4 of FIG. 3.

FIG. 5 is a sectional view of the present invention showing the EMI protective I/O connector holder plate fastened to the back sidewall of a case for computer.

FIG. 6 is a sectional view of the present invention showing the EMI protective I/O connector holder plate adhered with a nameplate and fastened to the back sidewall of a case for computer.

FIG. 7 is a side view in section of an alternate form of the present invention.

FIG. 8 illustrates the EMI protective I/O connector holder plate fastened to a window on the back sidewall of the mainframe of a computer according to the present invention.

FIG. 9 is a sectional view in an enlarged scale of the EMI protective I/O connector holder plate according to the present invention.

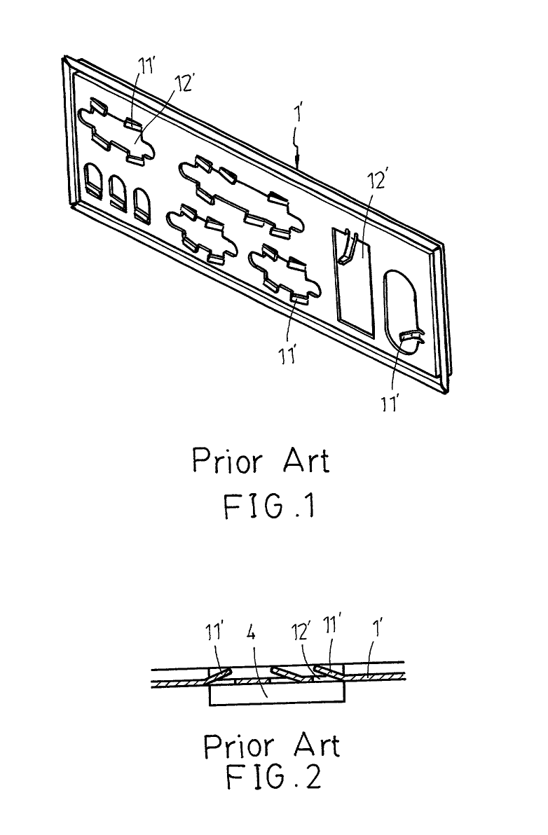

### DETAILED DESCRIPTION OF THE PREFERRED EMBODIMENT

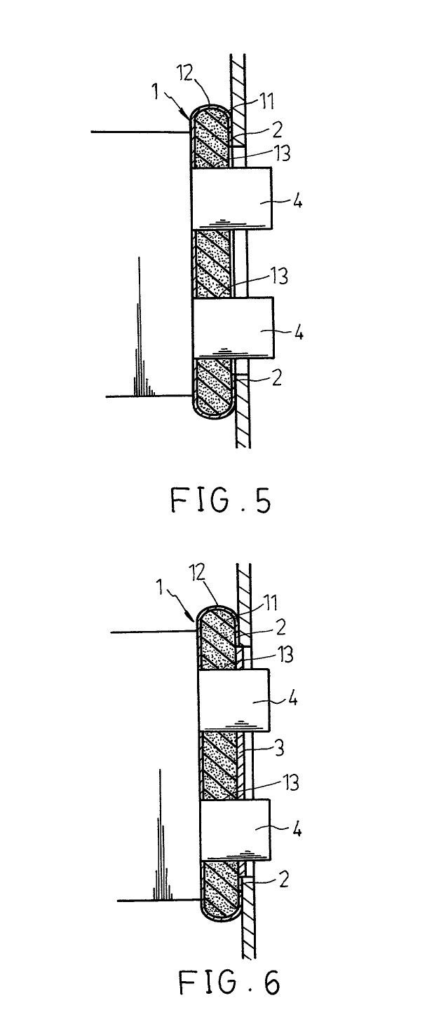

Referring to FIGS. From 3 through 5 and FIG. 8, an EMI protective I/O connector holder plate 1 is shown comprised of an electrically conductive shell 12 and a foamed lining 11 fastened to the inside wall of the electrically conductive shell 12. Because the foamed lining 11 has a thickness, the EMI protective I/O connector holder plate 1 has high spring power. The EMI protective I/O connector holder plate 1 has insertion holes 13 pierced through electrically conductive shell 12 and the foamed lining 11 and adapted to receive I/O connectors 4. After insertion of an I/O connector 4 in one insertion hole 13, the inserted I/O connector 4 is maintained in close contact with the electrically conductive shell 12 and the foamed lining 11 around the insertion hole 13, therefore the inserted I/O connector 4 is positively supported in position. The electrically conductive shell 12 has top and bottom edges turned backwardly inwards and covered over upper and lower part of the back sidewall of the foamed lining 11. Further, the EMI protective I/O connector holder plate 1 is back-glued 2 for adhering to a case for computer (see FIGS. 5 and 8).

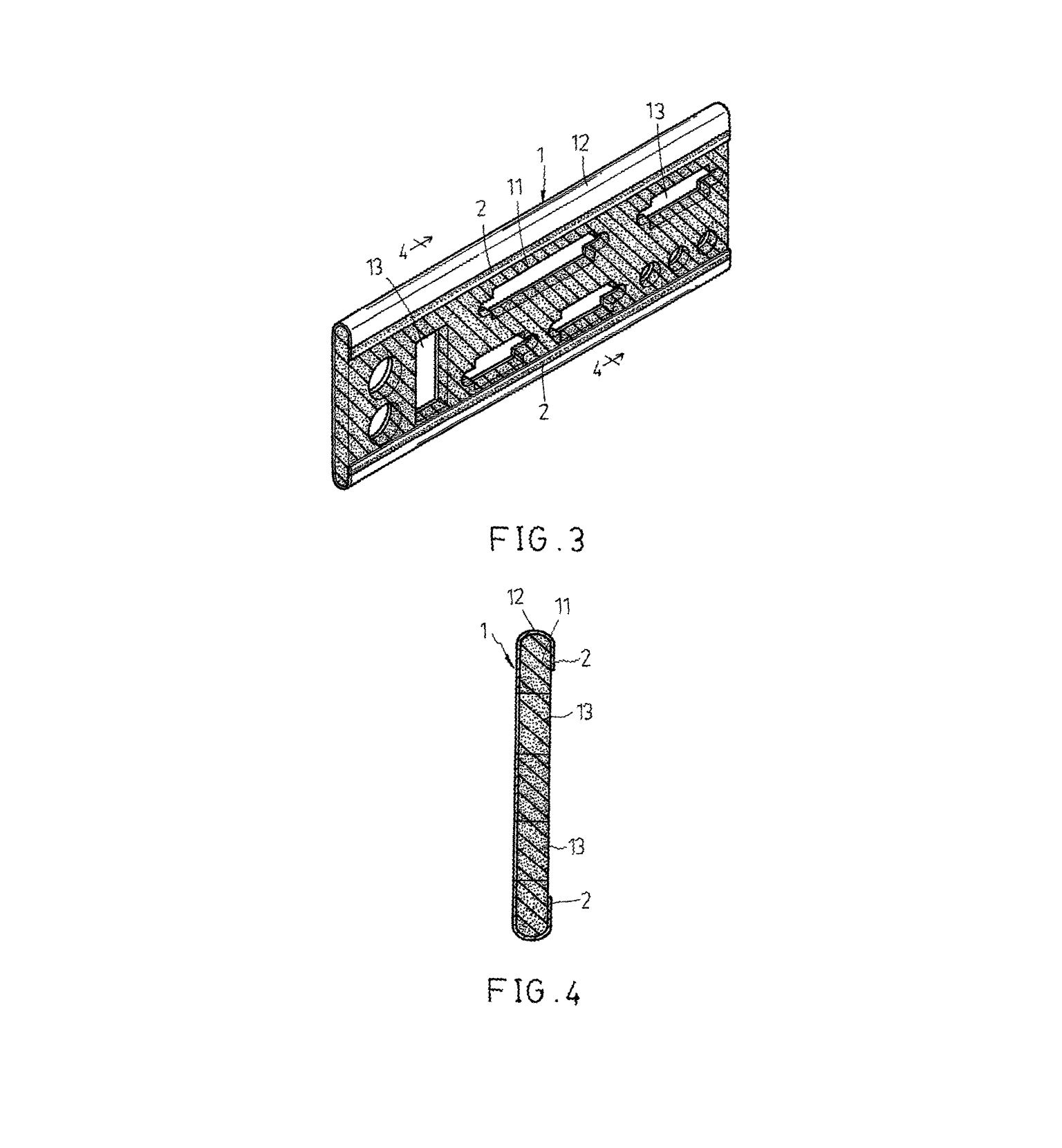

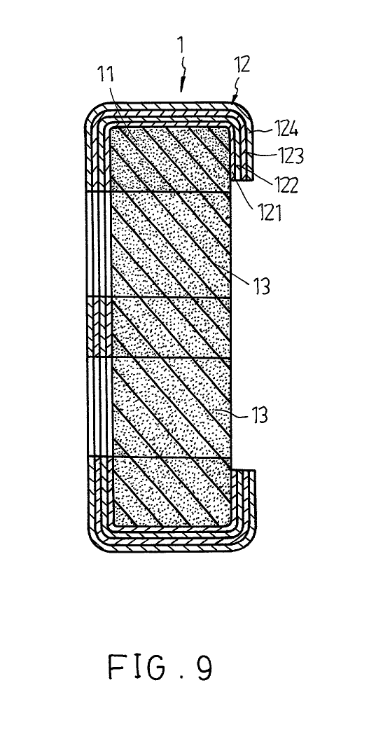

Referring to FIGS. 4 and 9, the electrically conductive shell 12 of the EMI protective I/O connector holder plate 1 is comprised of an inner layer of thermofusion gums 121, an outer layer of aluminum (copper) foil 124, an intermediate layer of cotton cloth 122 sandwiched in between the inner layer of thermofusion gums 121 and the outer layer of aluminum (copper) foil 124, and an intermediate layer of polyester film 123 sandwiched in between the intermediate layer of cotton cloth 122 and the outer layer of aluminum (copper) foil 124. The intermediate layer of cotton cloth 122 and the intermediate layer of polyester film 123 reinforce the structural strength of the outer layer of aluminum (copper) foil 124 and the bonding of the outer layer of aluminum (copper) foil 124 to the foamed lining 11.

Referring to FIG. 6, a nameplate 3 is adhered to the back sidewall of the foamed lining 11, and printed with signs corresponding to the insertion holes 13 for quick identification of the respective insertion holes 13. Further, the installation of the nameplate 3 supports the EMI protective I/O connector holder plate 1 against deformation.

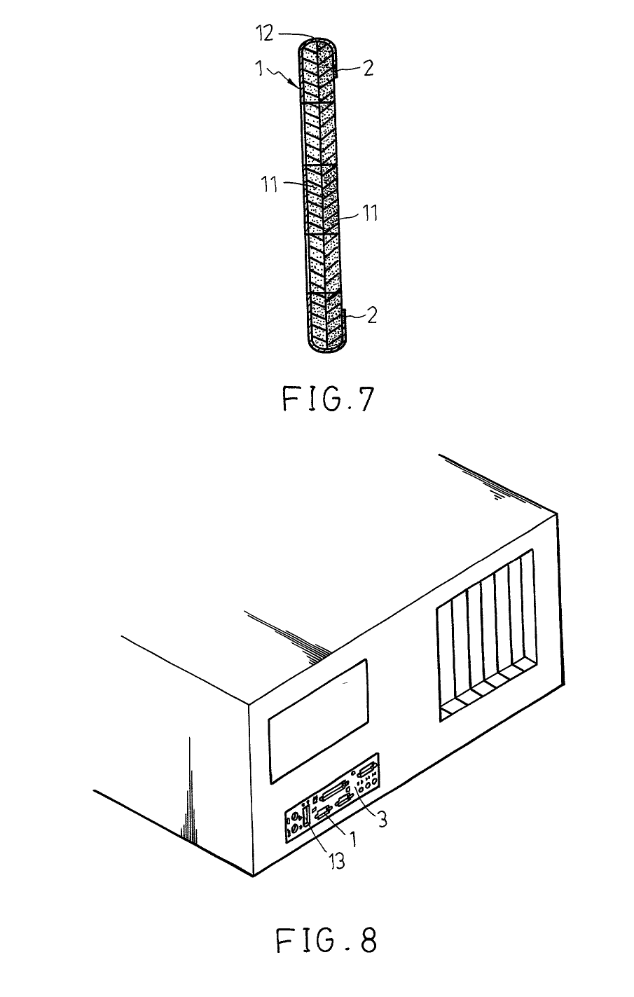

Referring to FIG. 7, two layers of foamed linings 11 may be adhered together and fastened to the electrically conductive shell 12. The outer layer of foamed lining can be made of foamed plastics relatively harder than the inner layer of foamed lining. The harder outer layer of foamed lining reinforces the structural strength of the EMI protective I/O connector holder plate 1 against deformation, and prevents vibration of the inserted I/O connectors 4.

It is to be understood that the drawings are designed for purposes of illustration only, and are not intended for use as a definition of the limits and scope of the invention disclosed.

What the invention claimed is:

1. An EMI (electromagnetic interference) protective I/O connector holder plate fastened to the back sidewall of a case for computer and having a plurality of insertion holes for the mounting of I/O connectors, said EMI protective I/O connector holder plate being back-glued and comprising a foamed lining and an electrically conductive shell covered on said foamed lining.

2. The EMI protective I/O connector holder plate of claim 1, wherein said foamed lining is comprised of multiple layers of foamed materials of different hardness.

3. The EMI protective I/O connector holder plate of claim 1 further comprising a nameplate adhered to a back sidewall thereof.

4. The EMI protective I/O connector holder plate of claim 1, wherein said electrically conductive shell is comprised of a layer of thermofusion gums, a layer of aluminum foil, a layer of cotton cloth 1, and a layer of polyester film.
